(19) United States
(12) Patent Application Publication
(10) Pub. No.: US 2024/0247404 A1
(43) Pub. Date: Jul. 25, 2024

(54) PRE-HEAT RINGS AND PROCESSING CHAMBERS INCLUDING BLACK QUARTZ, AND RELATED METHODS

(71) Applicant: Applied Materials, Inc., Santa Clara, CA (US)

(72) Inventors: Nimrod SMITH, Cupertino, CA (US); Zhepeng CONG, San Jose, CA (US); Ashur J. ATANOS, San Jose, CA (US)

(21) Appl. No.: 18/101,523

(22) Filed: Jan. 25, 2023

(51) Int. Cl. C30B 25/10; C30B 25/08; C30B 25/14; C30B 25/16

(52) U.S. Cl. CPC C30B 25/10; C30B 25/08; C30B 25/14; C30B 25/16

(57) ABSTRACT

Embodiments of the present disclosure generally relate to a pre-heat ring for use in a substrate processing chamber, and related methods. A pre-heat ring including black quartz (such as formed of black quartz) facilitates material properties that can facilitate heating benefits. In one or more embodiments, a pre-heat ring applicable for use in a semiconductor processing chamber includes one or more ring segments. The one or more ring segments include an inner edge defining an inner dimension, an outer edge defining an outer dimension, a first side surface between the inner edge and the outer edge, and a second side surface between the inner edge and the outer edge. The second side surface is opposing the first side surface. The one or more ring segments include black quartz. The black quartz includes silicon dioxide (SiO²) impregnated with undoped silicon (Si).

### BACKGROUND

### Field

Embodiments of the present disclosure generally relate to a pre-heat ring for use in a substrate processing chamber, and related methods.

### Description of the Related Art

Continuous reduction in size of semiconductor devices is dependent upon more precise control of, for instance, the flow and temperature of process gases delivered to a semiconductor process chamber. Typically, in a cross-flow chamber, a process gas may be delivered to the chamber and directed across the surface of a substrate to be processed. The temperature of the process gas may be affected by, for example a pre-heat ring.

Pre-heat rings have limitations with respect to heating and processing. For example, pre-heat rings that can quickly heat up also can cool down quickly between processing cycles, which can cause heating inefficiencies and increased power consumption. As another example, more pronounced temperature differentials throughout power cycles can cause increased fatigue of the pre-heat rings, which can cause fractures (e.g., cracks) in the pre-heat rings.

Therefore, a need exists for improved pre-heat rings.

### SUMMARY

Embodiments of the present disclosure generally relate to a pre-heat ring for use in a substrate processing chamber, and related methods.

In one or more embodiments, a pre-heat ring applicable for use in a semiconductor processing chamber includes one or more ring segments. The one or more ring segments include an inner edge defining an inner dimension, an outer edge defining an outer dimension, a first side surface between the inner edge and the outer edge, and a second side surface between the inner edge and the outer edge. The second side surface is opposing the first side surface. The one or more ring segments include black quartz. The black quartz includes silicon dioxide (SiO2) impregnated with undoped silicon (Si).

In one or more embodiments, a processing chamber applicable for use in semiconductor manufacturing includes a chamber body and a window, the chamber body and the window at least partially defining a processing volume. The processing chamber includes a plurality of heat sources configured to heat the processing volume, a substrate support disposed in the processing volume, a liner configured to at least partially line the chamber body, and a pre-heat ring disposed in the processing chamber and at least partially supported by the liner. The pre-heat ring includes one or more ring segments including black quartz. The black quartz includes silicon dioxide (SiO2) impregnated with undoped silicon (Si).

In one or more embodiments, a method of processing substrates, suitable for use in semiconductor processing, includes heating a surface of the pre-heat ring and a substrate positioned on a substrate support in a processing volume of a chamber. The pre-heat ring is disposed outwardly of the substrate, and includes black quartz. The black quartz includes silicon dioxide (SiO2) impregnated with undoped silicon (Si). The method further includes flowing one or more process gases over the surface of the pre-heat ring to heat the one or more process gases, flowing the one or more process gases over the substrate to form one or more layers on the substrate, and exhausting the one or more process gases.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a partial schematic side cross-sectional view of a processing chamber including a process kit, according to one or more embodiments.

FIG. 2 is a schematic axonometric view of the pre-heat ring shown in FIG. 1, according to one or more embodiments.

FIG. 3 is a schematic top view of the pre-heat ring shown in FIG. 1, according to one or more embodiments.

FIG. 4 is a schematic axonometric view of a pre-heat ring, according to one or more embodiments.

FIG. 5 is a schematic top view of the pre-heat ring shown in FIG. 4, according to one or more embodiments.

FIG. 6 is a schematic axonometric view of a pre-heat ring, according to one or more embodiments.

FIG. 7 is a schematic top view of the pre-heat ring shown in FIG. 6, according to one or more embodiments.

FIG. 8A is a schematic side cross-sectional view of the pre-heat ring, along Section 8-8 shown in FIG. 2, according to one or more embodiments.

FIG. 8B is a schematic side cross-sectional view of a pre-heat ring, according to one or more embodiments.

FIG. 9 is a schematic side cross-sectional of a pre-heat ring, according to one or more embodiments.

FIG. 10A is a schematic side cross-sectional of a pre-heat ring, according to one or more embodiments.

FIG. 10B is a schematic side cross-sectional of a pre-heat ring, according to one or more embodiments.

FIG. 11 is a schematic side cross-sectional of a pre-heat ring, according to one or more embodiments.

FIG. 12 is a schematic flow diagram of a method of processing substrates, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relates to chambers, methods, apparatus, and related components for using a pre-heat ring in a substrate processing chamber. A pre-heat ring includes black quartz. The pre-heat ring including black quartz (such as formed of black quartz) facilitates material properties that can facilitate heating benefits.

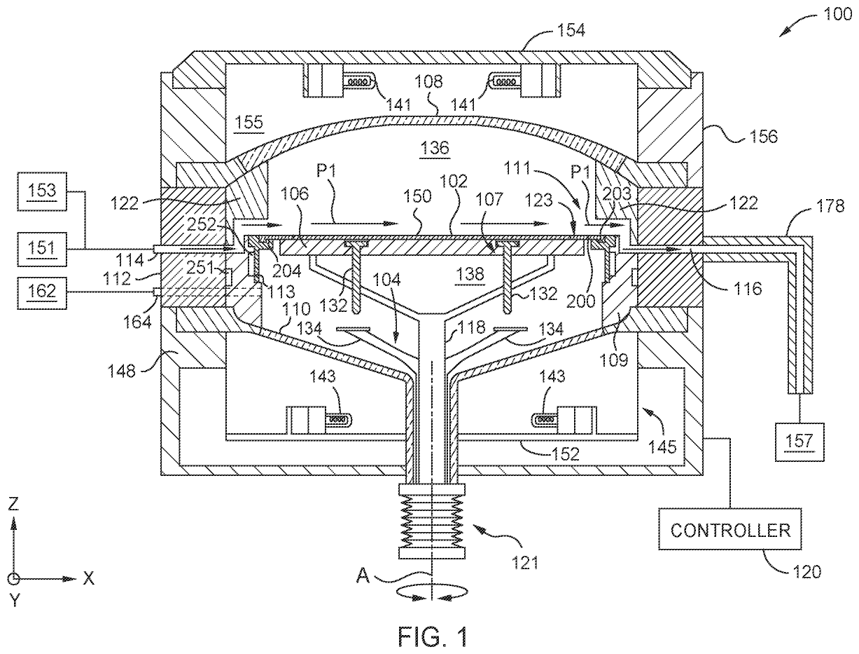

FIG. 1 is a partial schematic side cross-sectional view of a processing chamber 100 including a process kit 111, according to one or more embodiments. The processing chamber 100 is a deposition chamber. In one or more embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102.

The processing chamber 100 includes an upper body 156, a lower body 148 disposed below the upper body 156, and a flow module 112 disposed between the upper body 156 and the lower body 148. The upper body 156, the flow module 112, and the lower body 148 form at least part of a chamber body. Disposed within the chamber body is a substrate support 106, an upper window 108 (such as an upper dome), a lower window 110 (such as a lower dome), a plurality of upper lamps 141, and a plurality of lower lamps 143. As shown, a controller 120 is in communication with the processing chamber 100 and is used to control processes and methods, such as the operations of the methods described herein.

The substrate support 106 is disposed between the upper window 108 and the lower window 110. The substrate support 106 includes a support face 123 that supports the substrate 102. The plurality of upper lamps 141 are disposed between the upper window and a lid 154. The plurality of upper lamps 141 form a portion of the upper lamp module 155. The lid 154 may include a plurality of sensors (not shown) disposed therein for measuring the temperature within the processing chamber 100. The plurality of lower lamps 143 are disposed between the lower window 110 and a floor 152. The plurality of lower lamps 143 form a portion of a lower lamp module 145. The upper window 108 and the lower window 110 are formed of an energy transmissive material, such as quartz.

A process volume 136 and a purge volume 138 are formed between the upper window 108 and the lower window 110. The process volume 136 and the purge volume 138 are part of an internal volume defined at least partially by the upper window 108, the lower window 110, an upper liner 122, and one or more lower liners 109, 113. In one or more embodiments, the one or more lower liners 109, 113 include an outer liner 109 and an inner liner 113.

The internal volume has the substrate support 106 disposed therein. The substrate support 106 includes a top surface on which the substrate 102 is disposed. The substrate support 106 is attached to a shaft 118. The shaft 118 is connected to a motion assembly 121. The motion assembly 121 includes one or more actuators and/or adjustment devices that provide movement and/or adjustment for the shaft 118 and/or the substrate support 106 within the processing volume 136.

The substrate support 106 may include lift pin holes 107 disposed therein. The lift pin holes 107 are sized to accommodate lift pins 132 for lowering and lifting of the substrate 102 to and from the substrate support 106 before or and a deposition process is performed. The lift pins 132 may rest on lift pin stops 134 when the substrate support 106 is lowered from a process position to a transfer position. The lift pin stops 134 can be coupled to a second shaft 104 through a plurality of arms.

The flow module 112 includes a plurality of gas inlets 114, a plurality of purge gas inlets 164, and one or more gas exhaust outlets 116. In one or more embodiments, the plurality of gas inlets 114 and the plurality of purge gas inlets 164 are disposed on the opposite side of the flow module 112 from the one or more gas exhaust outlets 116. The upper liner 122 and the lower liners 109, 113 are disposed on an inner surface of the flow module 112 and protect the flow module 112 from reactive gases used during deposition operations and/or cleaning operations. The gas inlet(s) 114 and the purge gas inlet(s) 164 are each positioned to flow a gas parallel to the top surface 150 of a substrate 102 disposed within the process volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. One or more process gases supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). One or more purge gases supplied using the one or more purge gas sources 162 can include one or more inert gases (such as one or more of argon (Ar), helium (He), hydrogen (H₂), and/or nitrogen (N₂)). One or more cleaning gases supplied using the one or more cleaning gas sources 153 can include one or more of hydrogen (H) and/or chlorine (CI). In one or more embodiments, the one or more process gases include silicon phosphide (SiP) and/or phospine (PH₃), and the one or more cleaning gases include hydrochloric acid (HCl).

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. In one or more embodiments, the exhaust system 178 is disposed on an opposite side of the processing chamber 100 relative to the gas inlet(s) 114 and/or the purge gas inlets 164.

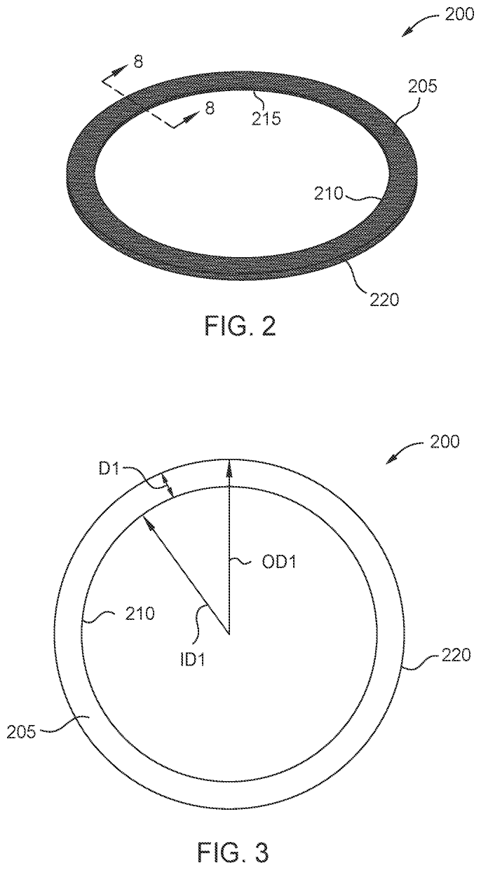

A pre-heat ring 200 is disposed outwardly of the substrate support 106. The pre-heat ring 200 is supported on a ledge of the inner liner 113. In one or more embodiments, an outer lip 203 of the pre-heat ring 200 interfaces with an inner lip 204 of the inner liner 113. The pre-heat ring 200 is described further in FIGS. 2-11. One or more gaps 251, 252 can be disposed between the lower liners 109, 113 and/or outwardly of the outer liner 109. The gaps 251, 252 can be filled with a gas, such as air and/or other gas(es). The gaps 251, 252 can function as thermal barriers and/or can be controlled to adjust temperatures in the gaps 251, 252.

The pre-heat ring 200 includes black quartz, as described further in relation to FIGS. 2 and 3. In one or more embodiments, the pre-heat ring 200 is formed of the black quartz. In one or more embodiments, the liners 109, 113, and/or 122 are formed of one or more of quartz (such as transparent quartz, e.g. clear quartz; opaque quartz, e.g., white or grey quartz; and/or the black quartz described for the pre-heat ring 200), silicon carbide (SiC), and/or graphite coated with SiC. In one or more embodiments, the inner liner 113 includes the black quartz described for the pre-heat ring 200), and the outer liner 109 include opaque quartz.

In the implementation shown in FIG. 1 the inner liner 113 and the pre-heat ring 200 are separate bodies. In one or more embodiments, the pre-heat ring 200 and the inner liner 113 are integrally formed as a monolithic body formed of the black quartz. In the implementation shown in FIG. 1 the inner liner 113 and the outer liner 109 are separate bodies. In one or more embodiments, the outer liner 109 and the inner liner 113 are integrally formed as a monolithic body.

One or more process gases P1 flow from the gas inlet(s) 114, into the processing volume 136, and over the substrate 102 to form (e.g., epitaxially grow) one or more layers on the substrate 102 while the lamps 141, 143 heat the pre-heat ring 200 and the substrate 102. After flowing over the substrate 102, the one or more process gases P1 flow out of the internal volume through the one or more gas exhaust outlets 116. The flow module 112 can be at least part of a sidewall of the processing chamber 100. The present disclosure also contemplates that one or more purge gases can be supplied to the purge volume 138 (through the plurality of purge gas inlets 164) during the deposition operation, and exhausted from the purge volume 138.

FIG. 2 is a schematic axonometric view of the pre-heat ring 200 shown in FIG. 1, according to one or more embodiments.

FIG. 3 is a schematic top view of the pre-heat ring 200 shown in FIG. 1, according to one or more embodiments.

The pre-heat ring 200 includes one or more ring segments. In one or more embodiments (and as shown in FIGS. 2 and 3), the pre-heat ring 200 includes one complete ring in the form of a complete circle. The pre-heat ring 200 has an inner edge 210 that defines an inner dimension ID1. The pre-heat ring 200 has an outer edge 220 that defines an outer dimension OD1. In one or more embodiments, the inner dimension ID1 is an inner radius and the outer dimension OD1 is an outer radius. In one or more embodiments, the outer dimension OD1 is a major dimension of the pre-heat ring 200 and the inner dimension ID1 is a minor dimension of the pre-heat ring 200. A first side surface 205 is between the inner edge 210 and the outer edge 220. A second side surface 215 is between the inner edge 210 and the outer edge 220. In one or more embodiments, the first side surface 205 is part of a flat face of the pre-heat ring 200, and the second side surface 215 is part of an L-shaped face of the pre-heat ring 200.

A distance D1 is between the inner dimension and the outer dimension. The distance D1 is less than or equal to 40 mm. In one or more embodiments, the distance D1 is within a range of 20 mm to 40 mm, such as 30 mm to 35 mm, such as 33 mm. The distance D1 is a distance ratio of the inner dimension ID1. The distance ratio is less than or equal to 0.25. In one or more embodiments, the distance ratio is within a range of 0.15 to 0.25, such as within a range of 0.17 to 0.19. In one or more embodiments, the distance ratio is about 0.18.

As discussed above, the pre-heat ring 200 includes the black quartz. The black quartz includes silicon dioxide (SiO₂) impregnated with undoped silicon (Si). The silicon dioxide used for manufacturing the black quartz is naturally occurring and crystalline. As shown in FIG. 2 using black surface shading, surfaces of the pre-heat ring 200 including the black quartz have a visual appearance that is black at room temperature. During heating of the pre-heat ring 200, the visual appearance can change to another solid color (such as orange). The solid black color, although present, is not shown in other Figures (such as FIGS. 1 and 3-11) for visual clarity purposes.

The black quartz has a composition including a mass percentage of the undoped silicon (e.g., an undoped silicon mass percentage) that is greater than 0.0% and less than or equal to 5.0%. In one or more embodiments, the undoped silicon mass percentage is within a range of 2.4% to 2.6%. In one or more embodiments, the undoped silicon mass percentage is about 2.5%.

A mass percentage of the silicon dioxide (e.g., a silicon dioxide mass percentage) in the composition of the black quartz is greater than or equal to 94.0%. In one or more embodiments, the silicon dioxide mass percentage is within a range of 96.4% to 97.6%. A sum of the undoped silicon mass percentage and the silicon dioxide mass percentage added together is greater than or equal to 99.0% such that impurities (for example carbon and/or metal(s)) have an impurity mass percentage that is 1.0% or less. The black quartz is hence substantially free from carbon and other impurities. In one or more embodiments, the sum of the undoped silicon mass percentage of the undoped silicon and the silicon dioxide mass percentage is greater than or equal to 99.9%. In one or more embodiments, the sum of the undoped silicon mass percentage of the undoped silicon and the silicon dioxide mass percentage is greater than or equal to 99.995%. Therefore, the impurities in the black quartz are less than or equal to 1%.

The black quartz has thermal properties that facilitate quickly and efficiently heating the pre-heat ring 200. The black quartz of the one or more ring segments has an emissivity that is greater than or equal to 0.75 at 1,000 degrees Celsius. In one or more embodiments, the emissivity of the black quartz is within a range of 0.8 to 0.9 at 1,000 degrees Celsius. The black quartz has a thermal conductivity that is less than 10.0 W/m-K. In one or more embodiments, the thermal conductivity of the black quartz is less than 5.0 W/m-K, such as less than 3.0 W/m-K. In one or more embodiments, the thermal conductivity of the black quartz is about 1.5.

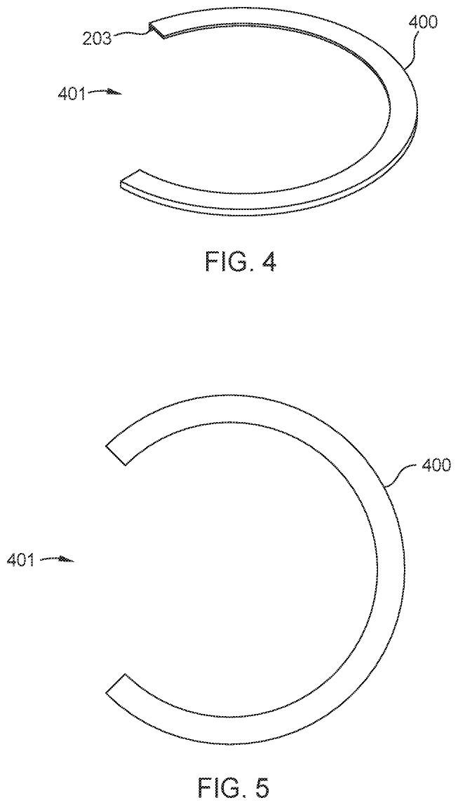

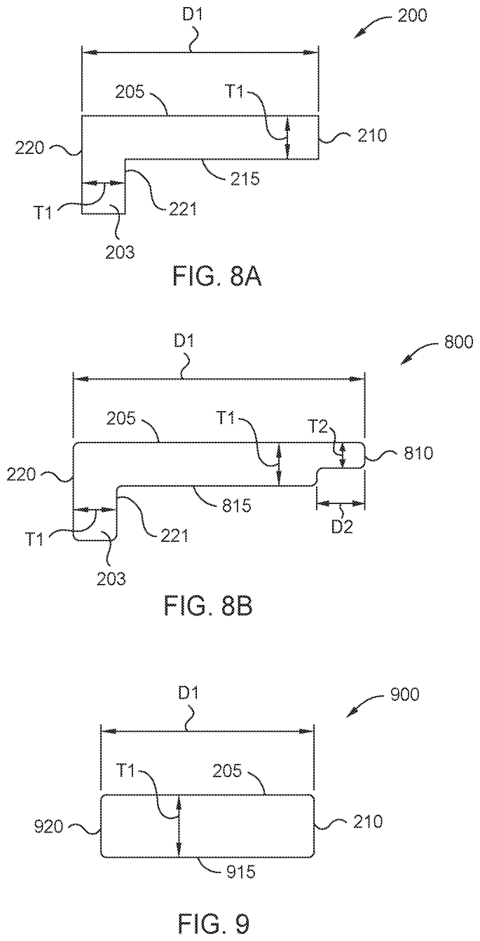

FIG. 4 is a schematic axonometric view of a pre-heat ring 400, according to one or more embodiments. In the implementation shown in FIG. 4, the pre-heat ring 400 has the cross-section shown in FIG. 8A. Other cross-sections (such as other cross-sections described herein, for example the cross-section shown in FIGS. 8B-11) can be used for the pre-heat ring 400.

FIG. 5 is a schematic top view of the pre-heat ring 400 shown in FIG. 4, according to one or more embodiments.

The pre-heat ring 400 is similar to the pre-heat ring 200 shown in FIG. 2, and includes one or more of the aspects, features, components, properties, and/or operations thereof. The pre-heat ring 400 can be used in place of the pre-heat ring 200 in FIG. 1. The pre-heat ring 400 is a C-ring that includes one ring segment in the shape of a “C” and has a gap 401.

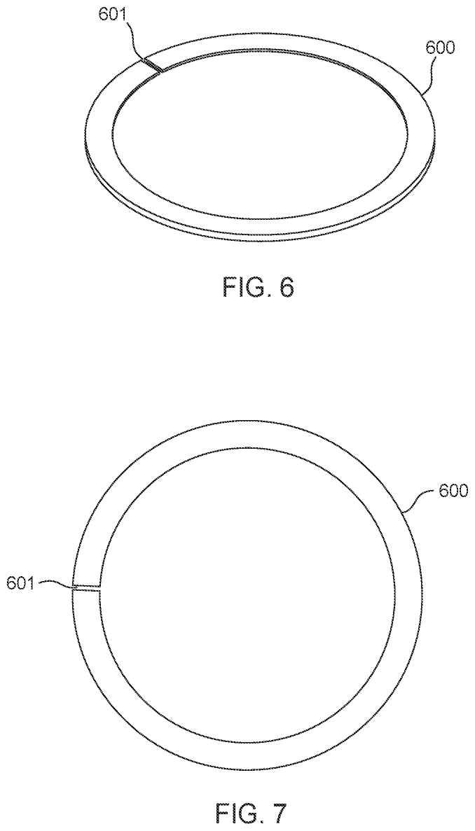

FIG. 6 is a schematic axonometric view of a pre-heat ring 600, according to one or more embodiments.

In the implementation shown in FIG. 6, the pre-heat ring 600 has the cross-section shown in FIG. 8A. Other cross-sections (such as other cross-sections described herein, for example the cross-section shown in FIGS. 8B-11) can be used for the pre-heat ring 600.

FIG. 7 is a schematic top view of the pre-heat ring 600 shown in FIG. 6, according to one or more embodiments.

The notched pre-heat ring 600 is similar to the pre-heat ring 200 shown in FIG. 2, and includes one or more of the aspects, features, components, properties, and/or operations thereof. The pre-heat ring 600 can be used in place of the pre-heat ring 200 in FIG. 1. The pre-heat ring 600 includes one ring segment that has a notch defining a gap 601.

FIG. 8A is a schematic side cross-sectional view of the pre-heat ring 200, along Section 8-8 shown in FIG. 2, according to one or more embodiments. A cross-section of the one or more ring segments of the pre-heat ring 200 is L-shaped.

A thickness T1 between the first side surface 205 and the second side surface 215 is less than or equal to 5.0 mm, such as 4.00 mm or less. The thickness T1 is 1.00 mm or larger, such as 1.2 mm or larger. In one or more embodiments, the thickness T1 is 3.0 mm or less, such as less than or equal to 2.0 mm. In one or more embodiments, the thickness T1 is within a range of 1.2 mm to 2.0 mm. In one or more embodiments, the thickness T1 is within a range of 1.2 mm to 3.0 mm, such as 2.0 mm to 3.0 mm. Other values (such as 0.8 mm or larger, or larger than 3.0 mm) are contemplated for the thickness T1. In one or more embodiments, the thickness T1 is used throughout the cross-section of the pre-heat ring 200. For example, the thickness T1 can be used between the outer edge 220 and an inner surface 221 of the outer lip 203 (as shown in FIG. 8A).

The thickness T1 is a thickness ratio of the inner dimension ID1. The thickness ratio is less than or equal to 0.025. In one or more embodiments, the thickness ratio is less than or equal to 0.020, such as within a range of 0.017 to 0.019. In one or more embodiments, the thickness ratio is about 0.018. In one or more embodiments, the thickness ratio is less than or equal to 0.015.

The thickness T1 and the black quartz facilitate a reduced mass of the pre-heat ring 200, and beneficial energy (e.g., infrared (IR)) blockage. For example, thermal process uniformity is facilitated while facilitating quickly and efficiently heating the pre-heat ring 200 (e.g., heating the first side surface 205) and reduced heat loss (e.g., reduced conduction away from the first side surface 205 and into the pre-heat ring 200, and reduced conduction and convection to volumes and components around the pre-heat ring 200) between thermal processing cycles. As another example, IR blockage is facilitated for efficient heating of process gases and the substrate with reduced heat loss to areas below the pre-heat ring 200. The quick and efficient heating and reduced heat loss facilitate reduced power consumption and thermal non-uniformities. As another example, the quick heating and reduced heat loss of the first side surface 205 facilitates increased dopant burn off in the process volume 135 between processing cycles, which facilitates reduced contamination, reduced memory effect, and enhanced device performance.

The outer edge 220 is taller than the inner edge 210.

FIG. 8B is a schematic side cross-sectional view of a pre-heat ring 800, according to one or more embodiments. Similar to the pre-heat ring 200 of FIG. 8A, a cross-section of the one or more ring segments of the pre-heat ring 800 is L-shaped but has a recess formed on the inner edge 801. The recess forms a stepped surface at the radially inward and lower edge of the pre-heat ring 800. The preheat ring 800 has a thickness T2 adjacent the stepped surface, and the thickness T2 is 1.00 mm or larger, such 1.2 mm or larger. In one or more embodiments, the thickness T2 is 3.0 mm or less, such as less than or equal to 2.0 mm. In one or more embodiments, the thickness T2 is within a range of 1.2 mm to 2.0 mm. In one or more embodiments, the thickness T2 is within a range of 1.2 mm to 3.0 mm, such as 2.0 mm to 3.0 mm. Other values (such as 0.8 mm or larger, or larger than 3.0 mm) are contemplated for the thickness T2. The thickness T2 is less than the thickness T1.

A distance D2 defines the width of the recess which defines the step. The distance D2 is within a range of 0 mm to 40 mm. The distance D2 is less than the distance D1. In one or more embodiments, the distance D2 is within a range of 0 mm to a value that is equal to the distance D1 minus the thickness T1. The offset of the inner edge 801 reduces a width of a second side surface 815. All other dimensions of the pre-heat ring 800 are identical to the pre-heat ring 200 shown in FIG. 8A.

FIG. 9 is a schematic side cross-sectional of a pre-heat ring 900, according to one or more embodiments. A cross-section of the pre-heat ring 900 is rectangular. The pre-heat ring 900 is similar to the pre-heat ring 200 shown in FIG. 2, and includes one or more of the aspects, features, components, properties, and/or operations thereof. The pre-heat ring 900 can be used in place of the pre-heat ring 200 in FIG. 1.

The pre-heat ring 900 includes the inner edge 210, the first side surface 205, an outer edge 920, and a second side surface 915 that is part of a second flat face. The inner edge 210 about the same in height as the outer edge 920. The first side surface 205 is about the same in length as the second side surface 915. In FIG. 9, the vertices of the rectangular cross section are rounded. The present disclosure contemplates that one or more vertices may not be rounded (e.g., can be squared as is shown in FIG. 8A).

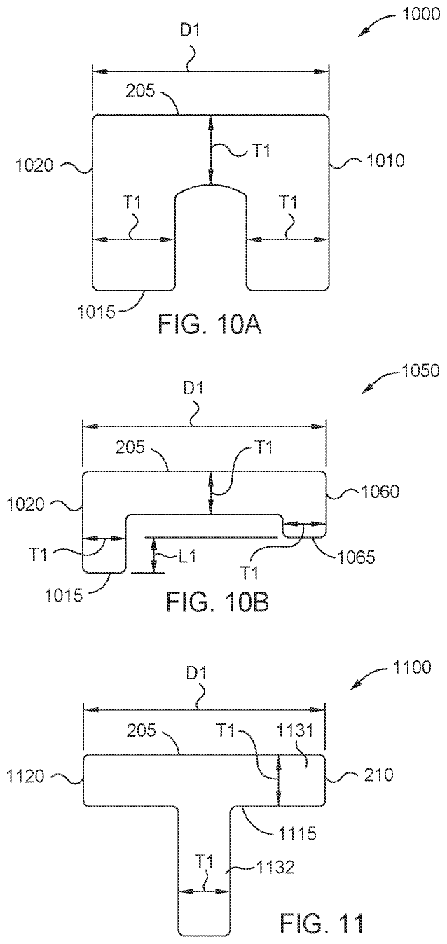

FIG. 10A is a schematic side cross-sectional of a pre-heat ring 1000, according to one or more embodiments. A cross-section of the pre-heat ring 1000 is U-shaped, and the pre-heat ring 1000 is oriented into the shape of an upside down “U” such that the “U” faces down. The pre-heat ring 1000 is similar to the pre-heat ring 200 shown in FIG. 2, and includes one or more of the aspects, features, components, properties, and/or operations thereof. The pre-heat ring 1000 can be used in place of the pre-heat ring 200 in FIG. 1.

The pre-heat ring 1000 includes the first side surface 205, an inner edge 1010, an outer edge 1020, and a second side surface 1015 between the inner edge 1010 and the outer edge 1020. The inner edge 1010 is about the same in height as the outer edge 1020. The second side surface 1015 is part of a U-shaped face and has a first portion and a second portion. In FIG. 9, the vertices of U-shaped cross section are rounded. The present disclosure contemplates that one or more vertices may not be rounded (e.g., can be squared as is shown in FIG. 8A).

FIG. 10B is a schematic side cross-sectional of a pre-heat ring 1050, according to one or more embodiments. Similar to the pre-heat ring 1000 of FIG. 10A, a cross-section of the one or more ring segments of the pre-heat ring 1050 is “U” shaped with a recessed section on a right second side surface 1065. The thickness T1 of each arm of the “U” shape is equal. An inner edge 1060 is shorter than the outer edge 1020 by a length L1. In one or more embodiments, the length L1 is within a range of 0.0 mm to 12.0 mm, such as about 3.0 mm. The right second side surface 1065 is parallel to but not co-planar with a left second side surface 1066.

FIG. 11 is a schematic side cross-sectional of a pre-heat ring 1100, according to one or more embodiments. A cross-section of the pre-heat ring 1100 is T-shaped, and the pre-heat ring 1100 is oriented upright. The pre-heat ring 1100 is similar to the pre-heat ring 200 shown in FIG. 2, and includes one or more of the aspects, features, components, properties, and/or operations thereof. The pre-heat ring 1000 can be used in place of the pre-heat ring 200 in FIG. 1.

The pre-heat ring 1100 includes the inner edge 210, the first side surface 205, an outer edge 1120, and a second side surface 1115. The second side surface 1115 is part of a T-shaped face that opposes the flat face of the first side surface 205. The inner edge 210 is about the same in height as the outer edge 920. In FIG. 44, the vertices of the T-shaped cross section are rounded. The present disclosure contemplates that one or more vertices may not be rounded (e.g., can be squared as is shown in FIG. 8A). The cross-section of the pre-heat ring 1100 includes a first section 1131 and a second section 1132 intersecting the first section 1131. A longitudinal axis of the second section 1132 can be vertically aligned with a geometric center of the first section 1131, or can be misaligned from the geometric center of the first section 1131.

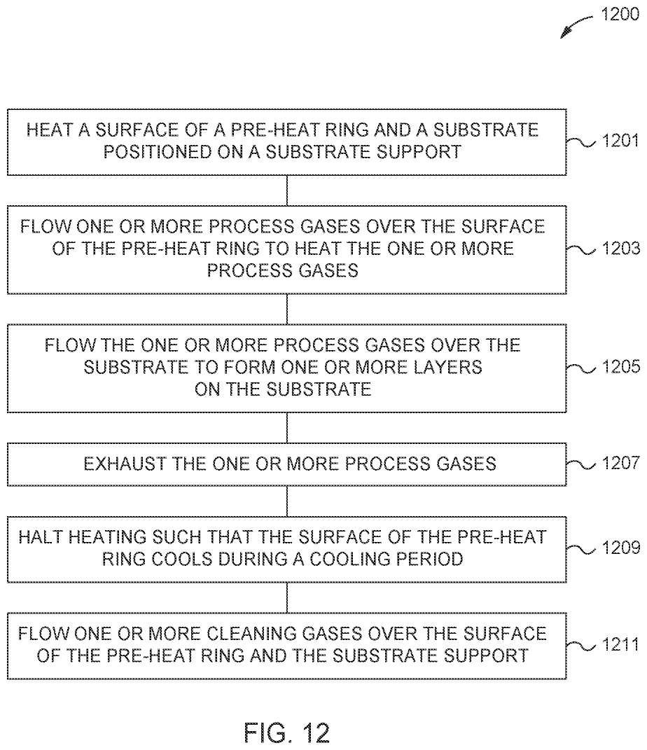

FIG. 12 is a schematic flow diagram of a method 1200 of processing substrates, according to one or more embodiments.

Operation 1201 includes heating a surface of a pre-heat ring 200 and the substrate 102. The substrate 102 is positioned on the substrate support 106 in the process volume 136 of the processing chamber 100. The pre-heat ring 200 is disposed outwardly of the substrate 102. For ease of demonstration, the processing chamber 100 and the pre-heat ring 200 are described, and other embodiments of the pre-heat ring (such as the implementations shown in FIGS. 4-7 and 9-11) and the processing chamber can be used and are considered for the method 1200. The pre-heat ring used includes the black quartz as described above.

Operation 1203 includes flowing one or more process gases over the surface (such as the first side surface 205) of the pre-heat ring 200. The one or more process gases are heated by contact with the pre-heat ring 200. The surface of the pre-heat ring 200 is heated at a heating rate that is 100 degrees Celsius per minute or higher. In one or more embodiments, the heating rate is 10 degrees Celsius per second or higher. In one or more embodiments, the heating rate is greater than 10 degrees Celsius per second and less than 30 degrees Celsius per second.

Operation 1205 includes flowing the heated one or more process gases over the substrate 102. The process gasses form (e.g., epitaxially) one or more layers on the substrate 102.

Operation 1207 includes exhausting the one or more process gases from the chamber. The gases are exhausted through the one or more gas exhaust outlets 116. The one or more gas exhaust outlets 116 are fluidly connected to an exhaust pump 157.

Operation 1209 includes halting the heating of the chamber. The heating is halted such that the surface of the pre-heat ring 200 cools at a cooling rate during a cooling period. The cooling rate is 50 degrees Celsius per minute or less.

Operation 1211 includes flowing one or more cleaning gases into the process volume 136 of the processing chamber 3500 through the gas inlet(s) 114. The cleaning gases flow over the surface of the pre-heat ring 200 and the substrate support 106.

Benefits of the present disclosure include a low thermal conductivity for black quartz and reduced mass for pre-heat rings, which facilitates reduced temperature loss between processing cycles while facilitating IR blocking. Such benefits facilitate enhanced gas activation and deposition uniformity, modularity in positioning of the pre-heat rings, enhanced growth rates, increased throughput, reduced processing times (e.g., heating times), reduced energy expenditures, and reduced costs. The reduced temperature fluctuation facilitates reduced thermal fatigue, reduced fracturing (e.g., cracking), and increased structural stability for pre-heat rings. Such benefits facilitate reductions in preventive maintenance and more predictable positioning of the pre-heat ring in the chamber. Such benefits also facilitate reduced wear and damage of other components (such as seals). The varied implementations of the pre-heat ring facilitate modularity and simplicity in retrofitting a variety of chambers that conduct different operations (e.g., different processing operations). Benefits also include-using the black quartz-enhanced etching with reduced effects (e.g., damage such as from etching) on pre-heat rings during cleaning operations that clean chambers. For example, the pre-heat rings can be etched using chemicals (such as hydrochloric acid (HCl)) at relatively high temperatures. Such benefits can be facilitated at relatively high deposition processing temperatures (including for example 900 degrees Celsius and higher) and relatively high cleaning temperatures (including for example 1000 degrees Celsius and higher).

The present disclosure describes pre-heat rings used in relation to epitaxial deposition chambers. The present disclosure contemplates that the pre-heat rings described herein can be used in relation to a variety of other chambers, such as other epitaxial chambers and/or chambers that conduct other processes.

It is contemplated that one or more aspects disclosed herein may be combined. As an example, one or more aspects, features, components, operations and/or properties of the processing chamber 100, the controller 120, the pre-heat ring 200, the pre-heat ring 400, the pre-heat ring 600, the pre-heat ring 900, the pre-heat ring 1000, the pre-heat ring 1100, and/or the method 1200 may be combined. For example, any of the cross-sections shown in FIGS. 8-11 can be used in any of the pre-heat rings shown in FIGS. 2-7. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A pre-heat ring applicable for use in a semiconductor processing chamber, comprising:
one or more ring segments comprising:
an inner edge defining an inner dimension,
an outer edge defining an outer dimension,
a first side surface between the inner edge and the outer edge, and
a second side surface between the inner edge and the outer edge, the second side surface opposing the first side surface; and
the one or more ring segments comprising black quartz, the black quartz comprising silicon dioxide (SiO₂) impregnated with undoped silicon (Si).

2. The pre-heat ring of claim 1, wherein a thickness between the first side surface and the second side surface is 3.0 mm or less.

3. The pre-heat ring of claim 1, wherein a thickness between the first side surface and the second side surface is a thickness ratio of the inner dimension, and the thickness ratio is 0.020 or less.

4. The pre-heat ring of claim 1, wherein a distance between the inner dimension and the outer dimension is a distance ratio of the inner dimension, and the distance ratio is 0.25 or less.

5. The pre-heat ring of claim 1, wherein the silicon dioxide (SiO₂) is naturally occurring and crystalline.

6. The pre-heat ring of claim 5, wherein the black quartz has a composition comprising an undoped silicon mass percentage greater than 0.0% and equal to or less than 5.0%.

7. The pre-heat ring of claim 6, wherein the undoped silicon mass percentage is within a range of 2.4% to 2.6%.

8. The pre-heat ring of claim 6, wherein the composition further comprises a silicon dioxide mass percentage that is 94.0% or higher.

9. The pre-heat ring of claim 8, wherein the undoped silicon mass percentage and the silicon dioxide mass percentage added together are 99.0% or higher.

10. The pre-heat ring of claim 1, wherein the one or more ring segments comprise a complete ring or a C-ring.

11. The pre-heat ring of claim 1, wherein the one or more ring segments have:
an emissivity that is 0.75 or higher at 1,000 degrees Celsius; and
a thermal conductivity that is less than 10.0 W/m-K.

12. A processing chamber applicable for use in semiconductor manufacturing, comprising:
a chamber body;
a window, the chamber body and the window at least partially defining a processing volume;
a plurality of heat sources configured to heat the processing volume;
a substrate support disposed in the processing volume;
a liner configured to at least partially line the chamber body; and
a pre-heat ring disposed in the processing chamber and at least partially supported by the liner, the pre-heat ring comprising:
one or more ring segments comprising black quartz, the black quartz comprising silicon dioxide (SiO₂) impregnated with undoped silicon (Si).

13. The processing chamber of claim 12, wherein the liner comprises the black quartz.

14. The processing chamber of claim 12, wherein the liner comprises opaque quartz.

15. The processing chamber of claim 12, wherein the one or more ring segments of the pre-heat ring and the liner are integrally formed as a monolithic body.

16. The processing chamber of claim 12, wherein the silicon dioxide (SiO₂) is naturally occurring and crystalline.

17. A method of processing substrates, suitable for use in semiconductor processing, the method comprising:
heating a surface of a pre-heat ring and a substrate positioned on a substrate support in a processing volume of a chamber, the pre-heat ring disposed outwardly of the substrate, and the pre-heat ring comprising one or more ring segments comprising black quartz, the black quartz comprising silicon dioxide (SiO₂) impregnated with undoped silicon (Si);
flowing one or more process gases over the surface of the pre-heat ring to heat the one or more process gases;
flowing the one or more process gases over the substrate to form one or more layers on the substrate; and
exhausting the one or more process gases.

18. The method of claim 17, wherein the surface of the pre-heat ring is heated at a heating rate that is 100 degrees Celsius per minute or higher.

19. The method of claim 18, further comprising:
halting heating such that the surface of the pre-heat ring cools at a cooling rate during a cooling period, wherein the cooling rate is 50 degrees Celsius per minute or less.

20. The method of claim 17, further comprising:
flowing one or more cleaning gases over the surface of the pre-heat ring and the substrate support.
